(19) United States
(12) Patent Application Publication
(10) Pub. No.: US 2025/0323007 A1
(43) Pub. Date: Oct. 16, 2025

(54) SEMICONDUCTOR RADIOACTIVE WAFER DECAY SAFETY AND OPERATION SYSTEM

(71) Applicant: Axcelis Technologies, Inc., Beverly, MA (US)

(72) Inventors: Peter DeRosa, Rockport, MA (US); Wilhelm Platow, Newburyport, MA (US); Justin McCabe, Boston, MA (US); Patrick Mayfield, Malden, MA (US); Paul Whalen, Beverly, MA (US); Clifton Brick, North Haverhill, NH (US); Gowrishankar Ramaraj, Bengaluru (IN); Guy Raiti, Atkinson, MA (US)

(21) Appl. No.: 19/175,305

(22) Filed: Apr. 10, 2025

Related U.S. Application Data
(60) Provisional application No. 63/632,478, filed on Apr. 10, 2024.

(51) Int. Cl. H01J 37/16; H01J 37/317

(52) U.S. Cl. CPC H01J 37/165; H01J 37/3171; H01J 2237/0203; H01J 2237/026

(57) ABSTRACT

A radiation safety apparatus for a semiconductor processing system has a safety fence with a support frame and radiation shields defining containment regions associated with load ports of the semiconductor processing system. The containment regions are associated with radioactive sources that emit radioactive radiation, where radiation shields attenuate the radiation to a region external to the containment regions. The radiation shields have access doors movably coupled to the support frame to provide access to the containment regions. Interlocks are provided with the access doors to selectively lock the access doors in a closed position to control the access to the containment regions from the external region through the access doors. A controller controls the interlocks based on a radiation decay associated with each of the radioactive sources and a predetermined safe radiation exposure level.

### REFERENCE TO RELATED APPLICATIONS

This application claims the benefit of U.S. Provisional Application Ser. No. 63/632,478 filed Apr. 10, 2024, entitled, “SEMICONDUCTOR RADIOACTIVE WAFER DECAY SAFETY AND OPERATION SYSTEM”, the contents of all of which are herein incorporated by reference in their entirety.

### TECHNICAL FIELD

The present invention relates generally to semiconductor processing systems, and more specifically to a radiation barrier for protecting an operator from a radioactive wafer after a high energy ion implantation.

### BACKGROUND

In the manufacture of semiconductor devices, ion implantation is used to dope semiconductors with impurities. Ion implantation systems are often utilized to dope a wafer, such as a semiconductor wafer, with ions from an ion beam, in order to either produce n- or p-type material doping, or to form passivation layers during fabrication of an integrated circuit. Such beam treatment is often used to selectively implant the wafer with impurities of a specified dopant material, at a predetermined energy level, and in controlled concentration, to produce a desired semiconductor material during fabrication of an integrated circuit. When used for doping a semiconductor wafer, for example, the ion implantation system injects a selected ion species into the wafer to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

Recent applications in ion implantation involve beam species and beam energies that exceed the fusion barrier in materials and dopants found in the wafers, leading to radioactive wafers after the ion implantation is performed. Such radioactive wafers effects the safety protocol, such as by implementing wait times, associated with subsequent processing or handling of any such wafers.

### SUMMARY

The following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

Aspects of the disclosure facilitate ion implantation processes for implanting ions into a wafer. According to one example, an ion implantation system is provided having an ion source configured to form an ion beam, a beamline assembly configured to selectively transport the ion beam, and an end station configured to accept the ion beam for implantation of the ions into a wafer.

In accordance with one exemplary aspect, a radiation safety apparatus is provided for a semiconductor processing system. The semiconductor processing system, for example, can comprise an ion implantation system. In accordance with one example, the radiation safety apparatus comprises a safety fence, wherein the safety fence comprises a support frame having a plurality of radiation shields operatively coupled thereto. The plurality of radiation shields, for example, define one or more containment regions, wherein the one or more containment regions are associated with one or more load ports of the semiconductor processing system. The one or more containment regions, for example, are further respectively associated with one or more radioactive sources that emit radioactive radiation, wherein the plurality of radiation shields are configured to attenuate the radioactive radiation to an external region that is external to the one or more containment regions. The plurality of radiation shields, for example, further comprise one or more access doors movably coupled to the support frame, wherein the one or more access doors are configured to provide selective access between the one or more containment regions and the external region.

The radiation safety apparatus, for example, further comprises one or more interlocks operatively coupled to the one or more access doors, wherein the one or more interlocks are configured to selectively lock the one or more access doors in a closed position, respectively, thereby controlling the selective access to the one or more containment regions from the external region through the one or more access doors. Further, a controller can be configured to control the one or more interlocks based on a predetermined radiation decay associated with each of the one or more radioactive sources and a predetermined safe radiation exposure level.

In one example, the controller is further configured to control the one or more interlocks based on an operational condition or settings of the semiconductor processing system, and the predetermined radiation decay can be based on a model of the wafers processed through the semiconductor processing system.

In another example, a plurality of wheels are operatively coupled to the support frame, whereby the support frame is selectively moveable with respect to the one or more load ports via the plurality of wheels. The safety fence can comprise a front side, a rear side, a left side, a right side, and a top side, wherein the plurality of radiation shields define the front side, the left side, and the right side of the safety fence. In one example, the rear side of the safety fence is operatively coupled to the semiconductor processing system via an equipment front end module (EFEM). The top side, for example, can be open to an overhead region, whereby the one or more load ports of the semiconductor processing system are accessible from the top side via an overhead hoist transport (OHT).

The one or more access doors, for example, can comprise two or more access doors, wherein the plurality of radiation shields define two or more containment regions respectively associated with the two or more access doors. The plurality of radiation shields, for example, can comprise one or more intermediate shields positioned between each of the two or more access doors, wherein the one or more intermediate shields extend from the front side toward the rear side and further attenuate the radioactive radiation between the one or more containment regions.

The radiation safety apparatus, for example, can further comprise one or more front opening unified pods (FOUPs) associated with each of the one or more load ports of the semiconductor processing system, whereby the one or more radioactive sources comprise radioactive semiconductor wafers contained within the one or more FOUPs.

In accordance with another aspect, an ion implantation system is provided, wherein the ion implantation system comprises an ion source configured to form and accelerate an ion beam at a high energy, and a beamline assembly configured to selectively control one or more properties of the ion beam. An end station of the ion implantation system, for example, is configured receive the ion beam for implantation of ions into one or more wafers, wherein the high energy of the ion beam induces a fusion reaction within the one or more wafers, thereby defining one or more radioactive sources that emit radioactive radiation.

One or more load ports, for example, are operatively coupled to the end station and configured to selectively transfer the one or more radioactive sources to one or more front opening unified pods (FOUPs), and a radiation safety apparatus us operatively coupled to the end station. The radiation safety apparatus, for example, comprises a safety fence comprises a support frame having a plurality of radiation shields operatively coupled thereto, thus defining one or more containment regions. The one or more containment regions, for example, are associated with the one or more load ports, and are further respectively associated with the one or more FOUPs. The plurality of radiation shields, for example, are configured to attenuate the radioactive radiation from the one or more radioactive sources to an external region that is external to the one or more containment regions. The plurality of radiation shields, for example, further comprise one or more access doors movably coupled to the support frame, wherein the one or more access doors are configured to provide selective access between the one or more containment regions and the external region.

In one example, one or more interlocks are operatively coupled to the one or more access doors, wherein the one or more interlocks are configured to selectively lock the one or more access doors in a closed position, respectively, thereby controlling the selective access to the one or more containment regions from the external region through the one or more access doors. A controller, for example, is further configured to control the one or more interlocks based on a modelled radiation decay associated with each of the one or more radioactive sources and a predetermined safe radiation exposure level. The controller, for example, is further configured to control the one or more interlocks based on an operational condition of one or more of the ion source, the beamline assembly, and the end station.

The safety fence can define a front side, a rear side, a left side, a right side, and a top side, wherein the plurality of radiation shields define the front side, the left side, and the right side of the safety fence, wherein the rear side is operatively coupled to the end station. An equipment front end module (EFEM) can be further operatively coupled to the end station, wherein the EFEM is configured to selectively contain the one or more FOUPs, and wherein the rear side of the safety fence is operatively coupled to the EFEM.

Further, according to another example, the one or more access doors comprise two or more access doors, and wherein the plurality of radiation shields define two or more containment regions respectively associated with the two or more access doors. The plurality of radiation shields, for example, comprise one or more intermediate shields positioned between each of the two or more access doors, wherein the one or more intermediate shields extend from the front side toward the rear side and further attenuate the radioactive radiation between the one or more containment regions. The top side, for example, can be open to an overhead region, whereby the one or more FOUPs are accessible from the top side.

In accordance with yet another aspect, a method for ameliorating radiation exposure in ion implantation processing is provided, whereby a plurality of front opening unified pods (FOUPs) are provided, and wherein a safety fence is positioned with respect to an equipment front end module (EFEM) of an ion implantation system. A plurality of radiation shields of the safety fence, for example, define a plurality of containment regions associated with a plurality of load ports of the EFEM. A first FOUP of the plurality of FOUPs, for example, is positioned with respect to a first load port of the plurality of load ports in a first containment region of the plurality of containment regions, wherein the first FOUP contains a first plurality of wafers.

The first plurality of wafers, for example, are transferred from the first FOUP through the first load port into the ion implantation system. A radiation activation of the first plurality of wafers, for example, is modelled based on ion implantation parameters associated with the ion implantation system to define a first radiation decay time associated with a predetermined safe radiation exposure level. Ions are further implanted into the first plurality of wafers at a high energy, thereby inducing nuclear fusion in the first plurality of wafers to define a first plurality of radioactive wafers. Concurrent with implanting the ions into the first plurality of wafers, access to the first FOUP from an external region is prevented via the safety fence. Preventing access to the first FOUP, for example, can comprise locking an access door associated with the first containment region.

The first plurality of radioactive wafers, for example, can be further transferred to back to the first FOUP or another FOUP. Access to the first FOUP or the another FOUP is further prevented from the external region through the safety fence until the first radiation decay time lapses. Access to the first FOUP or the another FOUP is permitted through the safety fence only after the first radiation decay time lapses, such as by unlocking the access door. The first FOUP or the another FOUP can be transferred through a top opening of the safety fence via an overhead hoist transport (OHT) after the first radiation decay time lapses.

In another example, a second FOUP of the plurality of FOUPs can be positioned with respect to a second load port of the plurality of load ports in a second containment region of the plurality of containment regions, wherein the second FOUP contains a second plurality of wafers. The second plurality of wafers, for example, can be transferred from the second FOUP through a second load port into the ion implantation system. A radiation activation of the second plurality of wafers can be modelled based on the ion implantation parameters associated with the ion implantation system to define a second radiation decay time associated with the predetermined safe radiation exposure level.

Ions can be implanted into the second plurality of wafers at the high energy, thereby inducing nuclear fusion in the second plurality of wafers to define a second plurality of radioactive wafers, and access to the second FOUP via the safety fence from an external region can be prevented concurrent with implanting the ions into the second plurality of wafers. The second plurality of radioactive wafers, for example, can be further transferred to the second FOUP or yet another FOUP, whereby access to the second FOUP or the yet another FOUP is prevented through the safety fence from the external region until the second radiation decay time lapses. Access to the second FOUP or the yet another FOUP, for example, can be permitted through the safety fence only after second radiation decay time lapses.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 is a block diagram of an exemplary semiconductor processing system in accordance with several example aspects of the present disclosure.

FIG. 2 is a table illustrating nuclear reactions based on implant species and material constituencies of a wafer in accordance with various examples of the present disclosure.

FIG. 3 is a front perspective view of a safety fence in accordance with various examples of the present disclosure.

FIG. 4 is a top elevation view of the safety fence of FIG. 3 in accordance with various examples of the present disclosure.

FIG. 5 is a rear perspective view of the safety fence of FIG. 3 in accordance with various examples of the present disclosure.

FIG. 6 is a front elevation view of a radiation safety apparatus in accordance with various examples of the present disclosure.

FIG. 7 is a front perspective view of the radiation safety apparatus of FIG. 6 in accordance with various examples of the present disclosure.

FIG. 8 is a flow diagram of a methodology for ameliorating radiation exposure in ion implantation processing in accordance with various examples of the present disclosure.

### DETAILED DESCRIPTION

The present disclosure is directed generally toward semiconductor processing systems, methods, and apparatuses for protecting an operator from radiation associated with semiconductor processing. More particularly, the present disclosure is directed toward a radiation barrier associated with an end station of an ion implantation system.

Accordingly, the present invention will now be described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features, circuits, or components in one embodiment, and may also or alternatively be fully or partially implemented in a common feature, circuit, or component in another embodiment. Further, several functional blocks, for example, may be implemented as software running on a common processor or controller.

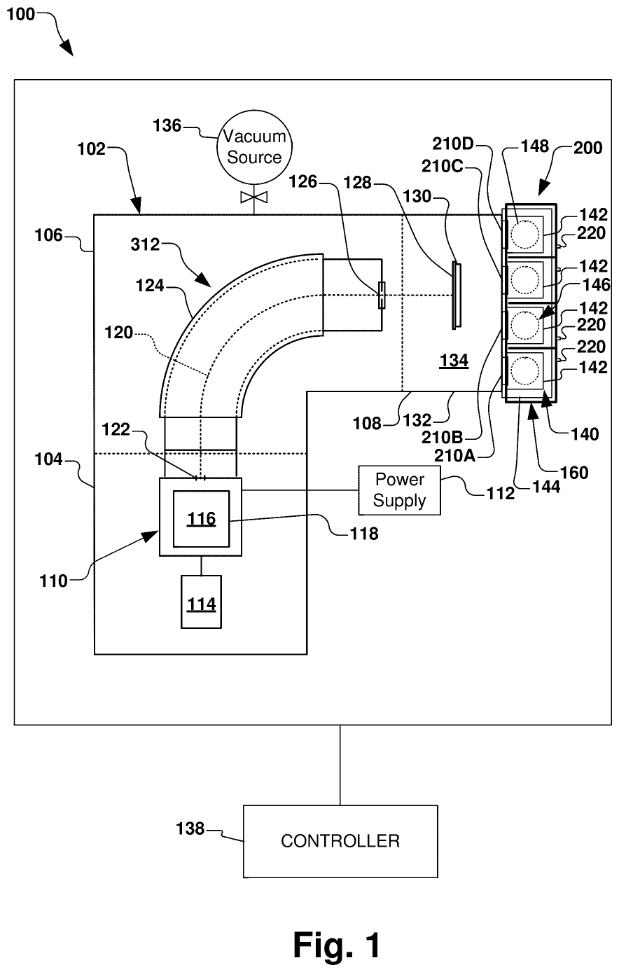

Referring now to the Figures, in order to gain a general understanding and context of the invention, FIG. 1 illustrates an exemplary semiconductor processing system 100. The semiconductor processing system 100 in the present example comprises an ion implantation system 102, however various other types of vacuum systems are also contemplated, such as plasma processing systems, or other semiconductor processing systems. It shall be thus understood that the systems, apparatuses, and methods of the present disclosure may be implemented in other semiconductor processing equipment such as CVD, PVD, MOCVD, etching equipment, and various other semiconductor processing equipment, and all such implementations are contemplated as falling within the scope of the present disclosure.

The ion implantation system 102, for example, comprises a terminal 104, a beamline assembly 106, and an end station 108. Generally speaking, an ion source 110 in the terminal 104 is coupled to a power supply 112, whereby a supply of source material 114 (also called a dopant material or dopant species) is provided to an arc chamber volume 116 within an arc chamber 118 and is ionized into a plurality of ions to form and extract an ion beam 120 via an extraction electrode 122. The ion beam 120 in the present example is directed through a beam-steering apparatus 124 (also called a source magnet), and out an aperture 126 towards the end station 108. In the end station 108, the ion beam 120 bombards a wafer 128 (e.g., a semiconductor such as a silicon wafer, a display panel, etc.), which is selectively clamped or mounted to a chuck 130 (e.g., an electrostatic chuck or ESC). Once embedded into the lattice of the wafer 128, the implanted ions change the physical and/or chemical properties of the wafer. Because of this, ion implantation is used in semiconductor device fabrication and in metal finishing, as well as various applications in materials science research.

The ion beam 120 of the present disclosure can take any form, such as a pencil or spot beam, a ribbon beam, a scanned beam, or any other form in which ions are directed toward end station 108, and all such forms are contemplated as falling within the scope of the disclosure.

According to one exemplary aspect, the end station 108 comprises a process chamber 132, (e.g., a vacuum chamber), wherein a process environment 134 is associated with the process chamber. The process environment 134 generally exists within the process chamber 132, and in one example, comprises a vacuum produced by a vacuum source 136 (e.g., a vacuum pump) coupled to the process chamber and configured to substantially evacuate the process chamber. Further, a controller 138 is provided for overall control of the semiconductor processing system 100 and components, thereof.

The present disclosure further provides for a transfer of the wafer 128 in batches (e.g., a plurality of wafers) between various semiconductor processes via a front opening universal pod (FOUP) system 140. The FOUP system 140, for example, comprises a plurality of FOUPs 142 and equipment front end module (EFEM) 144 configured to transfer wafer batches 146 from the process chamber 132 of the end station 108 to various other locations within a fabrication facility via an overhead hoist transport (OHT—not shown).

The semiconductor processing system 100 of the present disclosure contemplates various semiconductor processes that can involve providing high energies of a process medium at the wafer 128 that can exceed the so-called fusion barrier (also called the Coulomb barrier), which is a phenomenon where the electrostatic repulsion between two positively charged nuclei that must be overcome for fusion to occur. In the example of the ion implantation system 102 described above, when implanting various materials or dopants into the wafer 128 via the ion beam 120 at high energies, such an overcoming of the fusion barrier results in a radioactive wafer 148 (e.g., a radioactive source) after the ion implantation. The radioactive wafer 148 (e.g., in the wafer batches 146), for example, effects the safety protocol in wafer handling, and can be affect throughput associated with subsequent processing or handling of any such radioactive wafers.

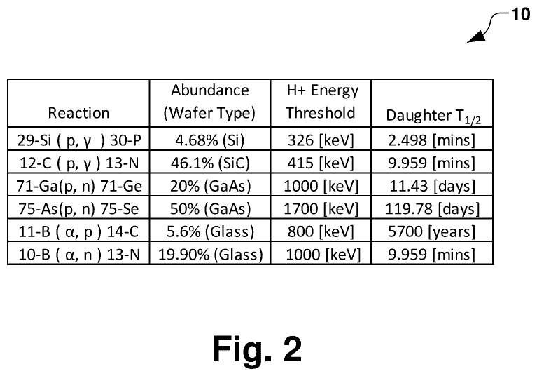

FIG. 2 illustrates various nuclear reactions 150 in one example, where H+ and He+ ions are implanted into the wafer, resulting in various nuclear reactions based on different material constituencies of the wafer 128 of FIG. 1, such as Si, GaAs, SiC, and Borosilicate glass. The radioactive decay mechanism of these nuclear reactions is known as Beta-decay. For example, the various nuclear reactions 150 provided in FIG. 2 can vary with respect to the type of nuclear reaction, relative concentration materials pertaining to the constituency of the wafer, the energy threshold of the H+ ions implanted into the wafer, and the half-life (T_{1/2}) of the daughter nucleus.

A personnel-safe exposure rate of less than 50 μRem/Hr exposure (an equivalent dose exposure rate) during the processing and handling of radioactive wafers 148 of FIG. 1 should be maintained for the health and safety of operators or other personnel who may be near the radioactive wafers. As such, the process flow associated with the processing (e.g., ion implantation) of radioactive wafers 148 can include wait times associated with the decaying radiation reaching the personnel-safe exposure rate, thus affecting throughput.

The radioactive wafers 148, for example, are transferred in the wafer batches 146 between various other semiconductor processes (not shown) via the FOUP system 140. The present disclosure contemplates an advantageous optimization of both the throughput and safety of the manufacturing process by providing an interlock-able radiation barrier 160 to shield personnel from a radiation field associated with the radioactive wafers 148 after processing, whereby access to the radioactive wafers and/or various ones of the plurality of FOUPs 142 containing the radioactive wafers is prevented until the personnel-safe exposure rate is reached.

This present disclosure, for example, contemplates applicability for all possible nuclear reactions associated with ion implantation, including implantation species having a large range of atomic number (e.g., 1≤Z≤83), as well as various constituencies of the wafer material (e.g., 1≤Z≤83), and all combinations, thereof. As the energy of desired ion implants continues to increase, the present disclosure appreciates that more fusion reactions will occur in wafers, and as such, the disclosure contemplates a system to effectively address safety concerns associated with decaying radiation in the radioactive wafer, while further optimizing or maximizing throughput of wafers through the system.

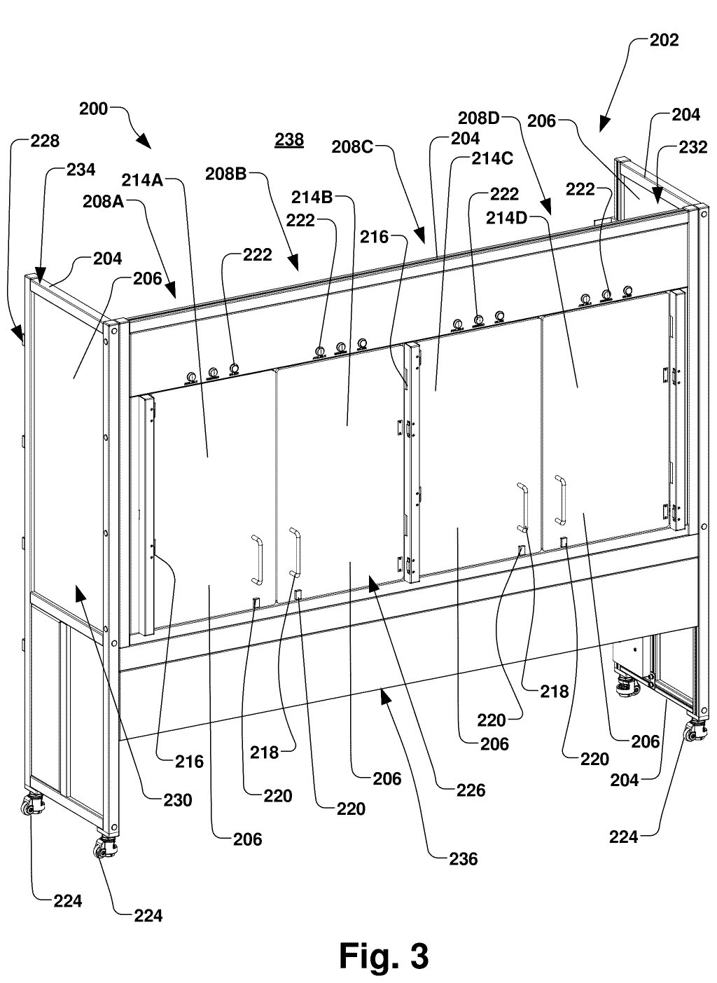

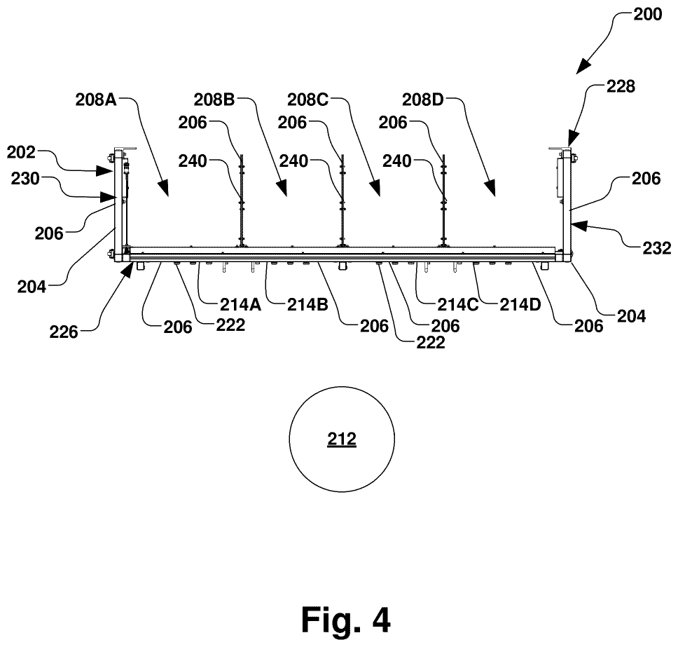

In accordance with one exemplary aspect of the disclosure, FIG. 3 illustrates a radiation safety apparatus 200 for a semiconductor processing system, such as the ion implantation system 102 of FIG. 1. For example, the interlock-able radiation barrier 160 of FIG. 1 can comprise the radiation safety apparatus 200 shown in FIG. 3. In accordance with one example, the radiation safety apparatus 200 of FIG. 3 comprises a safety fence 202, wherein the safety fence comprises a support frame 204 having a plurality of radiation shields 206 operatively coupled thereto. The plurality of radiation shields 206, for example, define one or more containment regions 208A-208D, as illustrated in FIG. 4. The one or more containment regions 208A-208D, for example, are associated with one or more load ports 210A-210D of the semiconductor processing system 100 shown in FIG. 1. The number of the one or more load ports 210A-210D of FIG. 1 and the number of one or more containment regions 208A-208D of FIG. 4 in the present example is four. However, it shall be understood that the radiation safety apparatus 200 of FIG. 3 can comprise any number of containment regions 208 and can be configured to correspond to the number of load ports 210 of FIG. 1, and any such configurations are contemplated as falling within the scope of the present disclosure.

The plurality of radiation shields 206, for example, are configured to attenuate the radioactive radiation from within the one or more containment regions 208A-208D to an external region 212 that is external to the respective one or more containment regions. The plurality of radiation shields 206, for example, are configured to ensure less than 50 μRem/Hr of equivalent dose rate exposure in the external region 212, and can comprise a material such as polyethylene or other material radio-opaque material that provides a sufficient radioactive barrier.

The plurality of radiation shields 206, for example, further comprise one or more access doors 214A-214D that are movably coupled to the support frame 204. For example, as illustrated in FIG. 3, the one or more access doors 214A-214D are rotatably coupled to the support frame 204 via one or more hinges 216, and can comprise one or more handles 218 for the operator to grasp. It shall be noted that, while not shown, the one or more access doors 214A-214D may be alternatively movably coupled to the support frame 204, such as in a sliding manner or other movable manner. Accordingly, the one or more access doors 214A-214D are configured to provide selective access between the one or more containment regions and the external region.

The one or more containment regions 208A-208D of FIG. 4, for example, can be further respectively associated with the radioactive wafers 148 of FIG. 1, whereby exposure an operator in the external region 212 can pose a health hazard when the radiation emitted from the radioactive wafers exceeds the personnel-safe exposure rate. Accordingly, the radiation safety apparatus 200 as shown in FIG. 3, for example, further comprises one or more interlocks 220 operatively coupled to the one or more access doors 214A-214D, wherein the one or more interlocks are configured to selectively lock the one or more access doors in a closed position (as illustrated in FIG. 3), respectively. The one or more interlocks 220, for example, may be further operably coupled to an indicator 222, (e.g., one or more lights, signals, or other displays), that can indicate a status of the one or more interlocks and/or a status of the one or more containment regions 208A-208D as being available, reserved, locked, unlocked, or other status. As such, the one or more interlocks 220, thereby control the selective access to the one or more containment regions 208A-208D from the external region 212 shown in FIG. 4 through the one or more access doors 214A-214D.

Further, the controller 138 of FIG. 1 can be configured to control the one or more interlocks 220 based on a predetermined radiation decay associated with the radioactive wafers 148 in each of the plurality of FOUPs 142. For example, the controller 138 can be configured to selectively control the one or more interlocks 220 in order to selectively permit access to each of the one or more containment regions 208A-208D through each of the one or more access doors 214A-214D of FIG. 4 based on a comparison of the predetermined radiation decay associated with the radioactive wafers and the predetermined personnel-safe radiation exposure level.

In one example, the controller 138 of FIG. 1 is further configured to control the one or more interlocks 220 based on an operational condition or settings of the semiconductor processing system 100, such as an energy or constituency of the ion beam 120, a material constituency, size, or other nature of the wafer 128, or other variables associated the semiconductor processing system. Further, the predetermined radiation decay can be based on a model of the wafers 128 being processed through the semiconductor processing system 100 using such operational condition(s) or settings, thereof.

In accordance with another example, the radiation safety apparatus 200 is selectively moveable with respect to the end station 108 and the one or more load ports 210A-210D of FIG. 1. For example, as illustrated in FIG. 3, the radiation safety apparatus 200 further comprises a plurality of wheels 224 operatively coupled to the support frame 204, whereby the support frame is selectively movable via the plurality of wheels. The safety fence 202, for example, can comprise a front side 226, a rear side 228, a left side 230, a right side 232, and a top side 234 as illustrated in FIG. 4, as well and a bottom side 236 illustrated in FIG. 3. In the present example, the plurality of radiation shields 206 can define at least the front side 226, the left side 230, and the right side 232 of the safety fence 202.

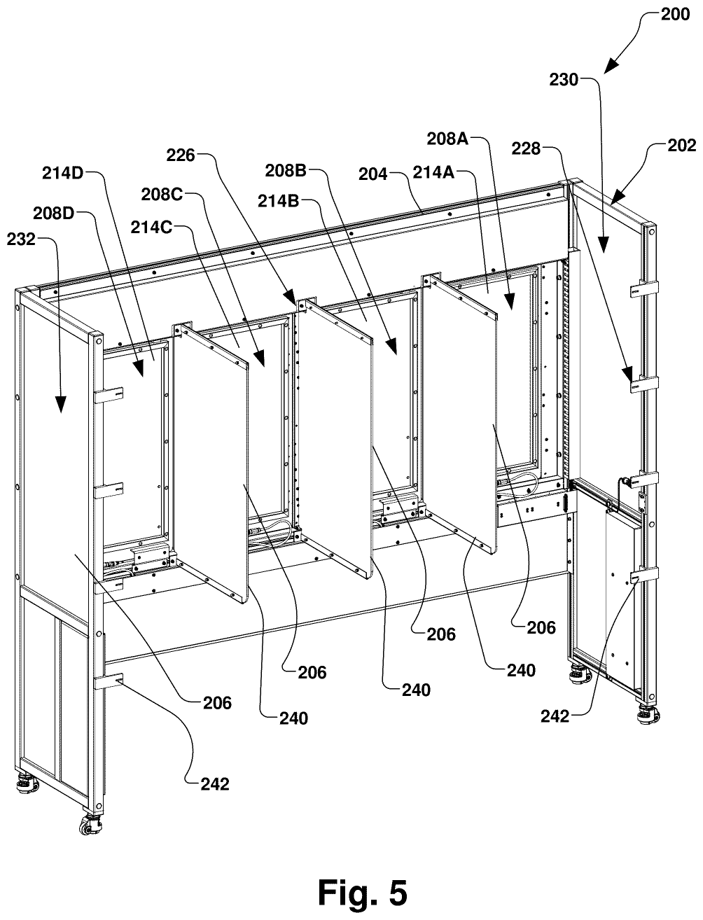

In accordance with another example, the plurality of radiation shields 206 can further comprise one or more intermediate shields 240 illustrated in FIGS. 4-5, whereby the one or more intermediate shields are positioned between each of two or more of the access doors 214A-214D. The one or more intermediate shields 240, for example, extend from the front side 226 toward the rear side 228 of the safety fence 202, as illustrated in FIG. 5, whereby the one or more intermediate shields are configured to further attenuate radioactive radiation between the one or more containment regions 208A-208D.

In one example, the safety fence 202 is operatively coupled to the end station 108 of the semiconductor processing system 100 of FIG. 1 via the EFEM 144. As such, the top side 234 illustrated in FIG. 3, for example, can be open to an overhead region 238, whereby the one or more load ports 210A-210D and the plurality of FOUPs 142 associated therewith can be are accessible from the top side via the OHT (not shown).

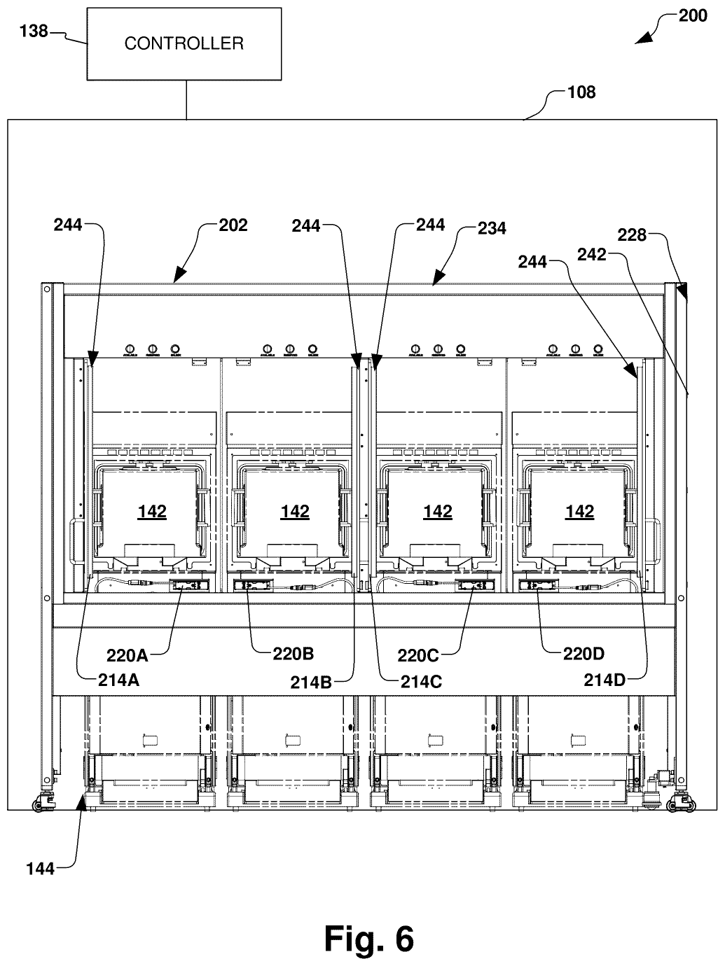

FIG. 6, for example, illustrates the safety fence 202 operatively coupled to the end station 108 via the EFEM 144. As illustrated in FIG. 6, the plurality of FOUPs 142 are accessible from the top side 234 of the safety fence 202, whereby the OHT can selectively place and/or retrieve the plurality of FOUPs with respect to the load ports described above. In the present example, the rear side 228 of the safety fence 202 comprises one or more brackets 242, illustrated in greater detail in FIG. 5, whereby the one or more brackets can selectively fixedly couple the safety fence 202 to the end station 108 of FIG. 1 or 6. FIG. 6 further illustrates the one or more access doors 214A-214D in an open position 244, whereby the plurality of FOUPs 142 are accessible by an operator.

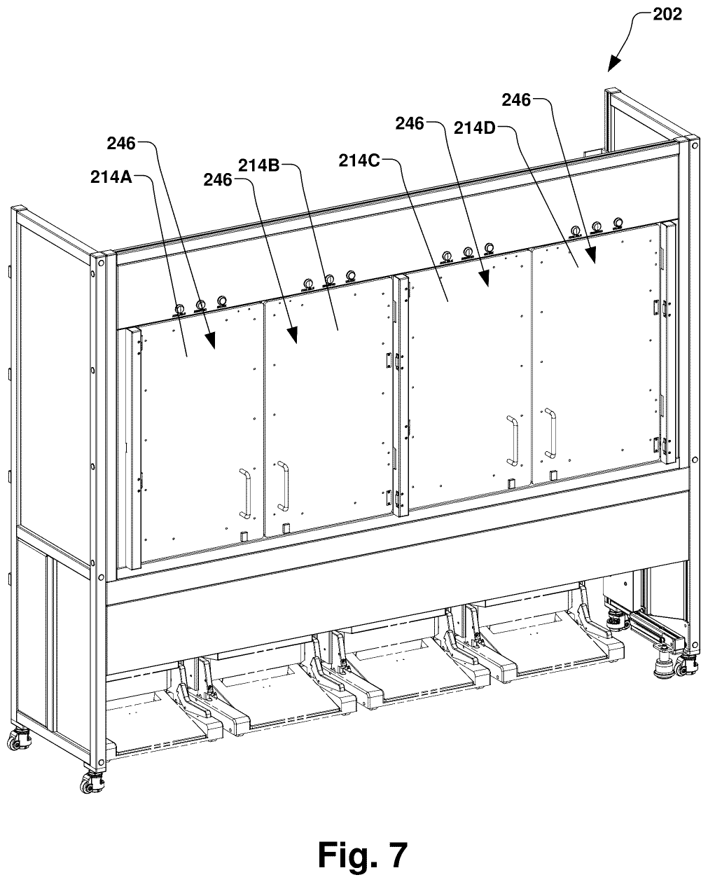

In order be in the open position 244, for example, the controller 138 can be configured to control the each of the one or more interlocks 220A-220D associated with each of the one or more access doors 214A-214D based on a comparison of the predetermined radiation decay associated with the radioactive wafers in the plurality of FOUPs and the predetermined personnel-safe radiation exposure level. For the one or more access doors 214A-214D to be in the open position 244 shown in FIG. 6, the comparison the predetermined radiation decay is lower than the predetermined personnel-safe radiation exposure level, whereby the controller 138 all of the one or more interlocks 220A-220D are unlocked. The one or more interlocks 220A-220D are independently controlled by the controller 138, whereby any of the one or more access doors 214A-214D may be independently permitted to be in the open position 244 shown in FIG. 6, or in a closed position 246, as illustrated in FIG. 7.

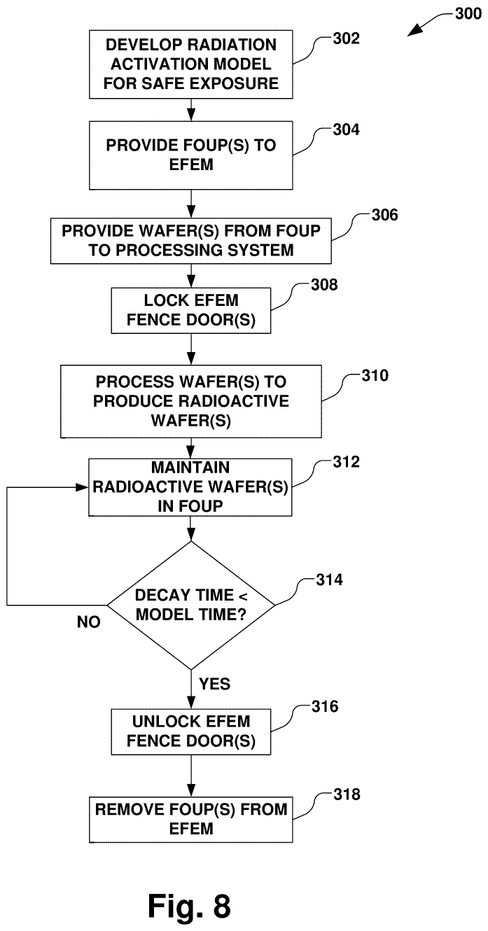

In accordance with yet another aspect, a method 300 is provided for ameliorating radiation exposure in ion implantation processing, as illustrated in FIG. 8. It should be noted that while exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

The method 300 of FIG. 8, for example, begins at act 302 by providing a radiation decay time that is associated with a predetermined safe radiation exposure level. Act 302 may further comprise establishing a predetermined safe radiation exposure level, such as the above-described personnel-safe exposure rate of less than 50 μRem/Hr exposure, or another exposure level. The radiation decay time, for example, can be defined based on a modeling of a radiation activation of wafers being implanted based on ion implantation parameters associated with the ion implantation system. In act 304, wafers to be processed are provided to the ion implantation system for implantation thereto, such as wafers 128 being provided to the end station 108 of FIG. 1 via the FOUPs 142 through the EFEM 144.

The radiation safety apparatus 200, as described above, for example, is positioned with respect to the EFEM of an ion implantation system, whereby the plurality of radiation shields of the safety fence, for example, define the plurality of containment regions associated with a plurality of load ports of the EFEM. For example, act 304 of FIG. 8 can position a first FOUP of the plurality of FOUPs with respect to a first load port of the plurality of load ports in a first containment region of the plurality of containment regions, wherein the first FOUP contains a first plurality of wafers.

In act 306, the first plurality of wafers, for example, can be selectively transferred from the first FOUP through the first load port into the ion implantation system. In act 308, access to the first FOUP from an external region is prevented via the safety fence. In act 310, ions are implanted into the first plurality of wafers at a high energy, thereby inducing nuclear fusion in the first plurality of wafers to define a first plurality of radioactive wafers. Preventing access to the first FOUP in act 308, for example, can comprise locking one or more access doors associated with the first containment region.

The first plurality of radioactive wafers, for example, can be further transferred to back to the first FOUP or to another FOUP (e.g., where wafers are not returned to the same FOUP from which they arrived) in act 312. Access to the first FOUP or the another FOUP is further prevented via the safety fence from the external region through the safety fence until the first radiation decay time lapses in act 314. For example, act 314 provides a wait time for the first radiation decay time to lapse before access to the first FOUP can again be achieved, such as by unlocking the access door associated with the first FOUP or the another FOUP in act 316. The first FOUP or the another FOUP can be transferred through a top opening of the safety fence via an overhead hoist transport (OHT) in act 318 after the first radiation decay time lapses.

The above methodology can be similarly repeated for multiple FOUPs, multiple implantation recipes, and various wafer configurations, whereby various access doors can be selectively locked or unlocked via the above-described interlocks. For example, a second FOUP of the plurality of FOUPs can be positioned with respect to a second load port of the plurality of load ports in a second containment region of the plurality of containment regions in act 304, wherein the second FOUP contains a second plurality of wafers. The second plurality of wafers, for example, can be transferred from the second FOUP through a second load port into the ion implantation system in act 306. A radiation activation of the second plurality of wafers can be further modelled in act 302 based on the ion implantation parameters associated with the ion implantation system to define a second radiation decay time associated with the predetermined safe radiation exposure level. The second radiation decay time can differ from the first radiation decay time.

Ions can be implanted into the second plurality of wafers in act 310 at the high energy, thereby inducing nuclear fusion in the second plurality of wafers to define a second plurality of radioactive wafers, whereby access to the second FOUP via the safety fence from an external region can be prevented in act 308 concurrent with implanting the ions into the second plurality of wafers. The second plurality of radioactive wafers, for example, can be further transferred to the second FOUP or yet another FOUP in act 312, whereby access to the second FOUP or the yet another FOUP is prevented through the safety fence from the external region until the second radiation decay time lapses in act 314. Access to the second FOUP or the yet another FOUP, for example, can be permitted through the safety fence only after second radiation decay time lapses in act 316, whereby the second FOUP or the yet another FOUP can be removed from the EFEM in act 318.

The present disclosure, for example, contemplates the safety fence as being a separate mechanical component or structure from the implant tool, as opposed to being a component of the EFEM or load port. For example, four FOUPs may be concurrently implemented, whereby wafers in a first FOUP are permitted to decay to the personnel-safe level post-implant, while the wafers in the remaining three FOUPs can be implanted. Once the wafers in the first FOUP are decayed, the first FOUP can be replaced while the other FOUPs are processed.

Accordingly, the interlocked load port fence provided herein advantageously access doors to prevent an operator of the system from being too proximate to radioactive fields emitted from the radioactive wafers post-implantation. In the external regions of the safety fence, safe levels of <50 μRem/Hr can be maintained, while the regions within the safety fence could exceed the 50 uRem/Hr of equivalent dose rate. The safety fence of the present disclosure, for example, allows access from the top side to enable commonly used Overhead Hoist Transport (OHT) systems to remove and place FOUPS for transfer to other semiconductor processing equipment within the semiconductor processing facility or fab.

The present disclosure, for example, contemplates applicability to any size FOUP or dimension of the wafer having radius between 1 mm and 500 mm, as well as any wafer composition, such as material having atomic numbers between 1 and 83. Further, the present disclosure contemplates the order of FOUPs being introduced/replaced/implanted can be in any orientation. While various examples are provided, the present disclosure is not be limited by sych examples, and contemplates any interlocked barrier that limits or prevents an operator from being deleteriously exposed to the radiation field.

It is noted that this system can advantageously increase throughput over convention systems, such as by utilizing two load ports for permitting the wafers to safely decay. As such, wait times associated with the wafer decay can be significantly reduced by the present disclosure by utiling four FOUPs in combination with the above-described safety fence, while still maintaining safe operation for the operator and allowing uninhibited access for the OHT system.

Although the invention has been illustrated and described with respect to one or more implementations, alterations and/or modifications may be made to the illustrated examples without departing from the spirit and scope of the appended claims. In particular regard to the various functions performed by the above described components or structures (blocks, units, engines, assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. The term “exemplary” as used herein is intended to imply an example, as opposed to best or superior. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A radiation safety apparatus for a semiconductor processing system, the radiation safety apparatus comprising:
a safety fence comprising:
a support frame; and
a plurality of radiation shields operatively coupled to the support frame and defining one or more containment regions, wherein the one or more containment regions are associated with one or more load ports of the semiconductor processing system, and wherein the one or more containment regions are further respectively associated with one or more radioactive sources that emit radioactive radiation, wherein the plurality of radiation shields are configured to attenuate the radioactive radiation to an external region that is external to the one or more containment regions, and wherein the plurality of radiation shields further comprise one or more access doors movably coupled to the support frame, wherein the one or more access doors are configured to provide selective access between the one or more containment regions and the external region;
one or more interlocks operatively coupled to the one or more access doors, wherein the one or more interlocks are configured to selectively lock the one or more access doors in a closed position, respectively, thereby controlling the selective access to the one or more containment regions from the external region through the one or more access doors; and
a controller configured to control the one or more interlocks based on a predetermined radiation decay associated with each of the one or more radioactive sources and a predetermined safe radiation exposure level.

2. The radiation safety apparatus of claim 1, wherein controller is further configured to control the one or more interlocks based on an operational condition of the semiconductor processing system.

3. The radiation safety apparatus of claim 1, wherein the predetermined radiation decay is based on a model.

4. The radiation safety apparatus of claim 1, further comprising a plurality of wheels operatively coupled to the support frame, whereby the support frame is selectively moveable with respect to the one or more load ports via the plurality of wheels.

5. The radiation safety apparatus of claim 1, wherein the safety fence comprises a front side, a rear side, a left side, a right side, and a top side, wherein the plurality of radiation shields define the front side, the left side, and the right side of the safety fence.

6. The radiation safety apparatus of claim 5, wherein the rear side is operatively coupled to the semiconductor processing system via an equipment front end module (EFEM).

7. The radiation safety apparatus of claim 5, wherein the one or more access doors comprise two or more access doors, and wherein the plurality of radiation shields define two or more containment regions respectively associated with the two or more access doors, wherein the plurality of radiation shields comprise one or more intermediate shields positioned between each of the two or more access doors, wherein the one or more intermediate shields extend from the front side toward the rear side and further attenuate the radioactive radiation between the one or more containment regions.

8. The radiation safety apparatus of claim 5, wherein the top side is open to an overhead region, whereby the one or more load ports of the semiconductor processing system are accessible from the top side.

9. The radiation safety apparatus of claim 1, further comprising one or more front opening unified pods (FOUPs) associated with each of the one or more load ports of the semiconductor processing system, whereby the one or more radioactive sources comprise radioactive semiconductor wafers contained within the one or more FOUPs.

10. An ion implantation system comprising:
an ion source configured to form and accelerate an ion beam at a high energy;
a beamline assembly configured to selectively control one or more properties of the ion beam;
an end station configured receive the ion beam for implantation of ions into one or more wafers, wherein the high energy of the ion beam induces a fusion reaction within the one or more wafers, thereby defining one or more radioactive sources that emit radioactive radiation;
one or more load ports operatively coupled to the end station and configured to selectively transfer the one or more radioactive sources to one or more front opening Unified Pods (FOUPs);
a radiation safety apparatus operatively coupled to the end station, the radiation safety apparatus comprising:
a safety fence comprising:
a support frame; and
a plurality of radiation shields operatively coupled to the support frame and defining one or more containment regions, wherein the one or more containment regions are associated with the one or more load ports, and wherein the one or more containment regions are further respectively associated with the one or more FOUPs, wherein the plurality of radiation shields are configured to attenuate the radioactive radiation from the one or more radioactive sources to an external region that is external to the one or more containment regions, and wherein the plurality of radiation shields further comprise one or more access doors movably coupled to the support frame, wherein the one or more access doors are configured to provide selective access between the one or more containment regions and the external region;
one or more interlocks operatively coupled to the one or more access doors, wherein the one or more interlocks are configured to selectively lock the one or more access doors in a closed position, respectively, thereby controlling the selective access to the one or more containment regions from the external region through the one or more access doors; and
a controller configured to control the one or more interlocks based on a modelled radiation decay associated with each of the one or more radioactive sources and a predetermined safe radiation exposure level.

11. The ion implantation system of claim 10, wherein the controller is further configured to control the one or more interlocks based on an operational condition of one or more of the ion source, the beamline assembly, and the end station.

12. The ion implantation system of claim 10, wherein the radiation safety apparatus further comprises a plurality of wheels operatively coupled to the support frame, whereby the support frame is selectively moveable with respect to the one or more load ports via the plurality of wheels.

13. The ion implantation system of claim 10, wherein the safety fence defines a front side, a rear side, a left side, a right side, and a top side, wherein the plurality of radiation shields define the front side, the left side, and the right side of the safety fence, and wherein the rear side is operatively coupled to the end station.

14. The ion implantation system of claim 13, wherein the one or more access doors comprise two or more access doors, and wherein the plurality of radiation shields define two or more containment regions respectively associated with the two or more access doors, wherein the plurality of radiation shields comprise one or more intermediate shields positioned between each of the two or more access doors, wherein the one or more intermediate shields extend from the front side toward the rear side and further attenuate the radioactive radiation between the one or more containment regions.

15. The ion implantation system of claim 13, wherein the top side is open to an overhead region, whereby the one or more FOUPs are accessible from the top side.

16. The ion implantation system of claim 10, further comprising an equipment front end module (EFEM) operatively coupled to the end station, wherein the EFEM is configured to selectively contain the one or more FOUPs, and wherein the radiation safety apparatus is operatively coupled to the EFEM.

17. A method for ameliorating radiation exposure in ion implantation processing, the method comprising:
providing a plurality of front opening unified pods (FOUPs);
positioning a safety fence with respect to an equipment front end module (EFEM) of an ion implantation system, wherein a plurality of radiation shields of the safety fence define a plurality of containment regions associated with a plurality of load ports of the EFEM;
positioning a first FOUP of the plurality of FOUPs with respect to a first load port of the plurality of load ports in a first containment region of the plurality of containment regions, wherein the first FOUP contains a first plurality of wafers;
transferring the first plurality of wafers from the first FOUP through the first load port into the ion implantation system;
modeling a radiation activation of the first plurality of wafers based on ion implantation parameters associated with the ion implantation system to define a first radiation decay time associated with a predetermined safe radiation exposure level;
implanting ions into the first plurality of wafers at a high energy, thereby inducing nuclear fusion in the first plurality of wafers to define a first plurality of radioactive wafers;
preventing access to the first FOUP via the safety fence from an external region concurrent with implanting the ions into the first plurality of wafers;
transferring the first plurality of radioactive wafers to the first FOUP;
preventing access to the first FOUP through the safety fence from the external region until the first radiation decay time lapses; and
permitting access to the first FOUP through the safety fence only after the first radiation decay time lapses.

18. The method of claim 17, further comprising transferring the first FOUP through a top opening of the safety fence via an overhead hoist transport (OHT) after the first radiation decay time lapses.

19. The method of claim 17, wherein preventing access to the first FOUP comprises locking an access door associated with the first containment region, and wherein permitting access to the first FOUP comprises unlocking the access door.

20. The method of claim 17, further comprising:
positioning a second FOUP of the plurality of FOUPs with respect to a second load port of the plurality of load ports in a second containment region of the plurality of containment regions, wherein the second FOUP contains a second plurality of wafers;
transferring the second plurality of wafers from the second FOUP through a second load port into the ion implantation system;
modeling a radiation activation of the second plurality of wafers based on the ion implantation parameters associated with the ion implantation system to define a second radiation decay time associated with the predetermined safe radiation exposure level;
implanting ions into the second plurality of wafers at the high energy, thereby inducing nuclear fusion in the second plurality of wafers to define a second plurality of radioactive wafers;
preventing access to the second FOUP via the safety fence from an external region concurrent with implanting the ions into the second plurality of wafers;
transferring the second plurality of radioactive wafers to the second FOUP;
preventing access to the second FOUP through the safety fence from the external region until the second radiation decay time lapses; and
permitting access to the second FOUP through the safety fence only after second radiation decay time lapses.
